(19) United States
(12) Patent Application Publication
(10) Pub. No.: US 2023/0097805 A1
(43) Pub. Date: Mar. 30, 2023

(54) COMPLEX FIELD-SHAPING BY FINE VARIATION OF LOCAL MATERIAL DENSITY OR PROPERTIES

(71) Applicant: Intel Corporation, Santa Clara, CA (US)

(72) Inventors: Samuel James BADER, Hillsboro, OR (US); Han Wui THEN, Portland, OR (US)

(21) Appl. No.: 17/485,232

(22) Filed: Sep. 24, 2021

(51) Int. Cl. H01L 29/40; H01L 29/20; H01L 29/205; H01L 29/778; H01L 21/76; H01L 21/765; H01L 29/66

(52) U.S. Cl. CPC H01L 29/404; H01L 29/2003; H01L 29/205; H01L 29/7786; H01L 21/7605; H01L 21/765; H01L 29/66462

(57) ABSTRACT

Embodiments disclosed herein include transistor devices and methods of forming such devices. In an embodiment, a transistor device comprises a channel, where the channel comprises a first semiconductor material. In an embodiment, a source contact is at a first end of the channel, and a drain contact at a second end of the channel. In an embodiment, a gate electrode is between the source contact and the drain contact, and a field plate extends from the gate electrode towards the drain contact. In an embodiment, a plurality of protrusions extend out from the field plate towards the channel, where the protrusions comprise a second semiconductor material

### TECHNICAL FIELD

Embodiments of the disclosure are in the field of semiconductor structures and processing and, in particular, to high-voltage transistors with semiconductor protrusions for field shaping.

### BACKGROUND

Due to its wide bandgap and high critical breakdown electric field, gallium nitride (GaN) transistors are great candidates for high voltage applications. High voltage applications may include power converters, radio-frequency (RF) power amplifiers, RF switches and other high voltage applications. However, simple transistor architectures, namely, having a single gate, source and drain, are not able to take advantage of these electrical properties. Such GaN transistors fall short of realizing the maximum breakdown voltage dictated by the material properties of GaN because drain electric field lines concentrate at the edge of the gate. This causes premature breakdown. The concentration of electric field lines is the result of complex interactions in the device and is typically experienced by most transistors regardless of material used for the channel. However, the electric field line concentration is particularly problematic in GaN transistors due to the high voltages.

### BRIEF DESCRIPTION OF THE DRAWINGS

FIG. 1 is a cross-sectional illustration of a transistor with a field plate and a semiconductor body with a dopant gradient below the field plate, in accordance with an embodiment.

FIG. 2A is a cross-sectional illustration of a transistor with a field plate and semiconductor protrusions with a non-uniform distribution density extending down from the field plate, in accordance with an embodiment.

FIG. 2B is a cross-sectional illustration of a transistor with a first field plate and a second field plate with semiconductor protrusions extending down from both the first field plate and the second field plate, in accordance with an embodiment.

FIG. 2C is a cross-sectional illustration of a transistor with a stepped field plate and semiconductor protrusions extending down from one of the stepped surfaces, in accordance with an embodiment.

FIG. 2D is a cross-sectional illustration of a transistor with a field plate with semiconductor protrusions extending down from the field plate into a graded dielectric layer, in accordance with an embodiment.

FIG. 3A is a cross-sectional illustration of a transistor with a source, a gate, and a drain over a semiconductor channel, in accordance with an embodiment.

FIG. 3B is a cross-sectional illustration of the transistor with a patterned resist layer over dielectric layer around the source, gate, and drain, in accordance with an embodiment.

FIG. 3C is a cross-sectional illustration of the transistor after the resist pattern is transferred into the dielectric layer, in accordance with an embodiment.

FIG. 3D is a cross-sectional illustration of the transistor after a semiconductor layer is disposed over the dielectric layer, in accordance with an embodiment.

FIG. 3E is a cross-sectional illustration of the transistor after a resist is disposed over the semiconductor layer, in accordance with an embodiment.

FIG. 3F is a cross-sectional illustration of the transistor after the semiconductor layer is patterned and the dielectric material is backfilled around the semiconductor layer, in accordance with an embodiment.

FIG. 3G is a cross-sectional illustration of the transistor after the semiconductor layer is recessed leaving behind only the semiconductor protrusions and a cavity over the protrusions, in accordance with an embodiment.

FIG. 3H is a cross-sectional illustration of the transistor after a field plate is disposed into the cavity over the semiconductor protrusions, in accordance with an embodiment.

FIG. 4 illustrates a computing device in accordance with one implementation of an embodiment of the disclosure.

FIG. 5 is an interposer implementing one or more embodiments of the disclosure.

### DESCRIPTION OF THE EMBODIMENTS

Embodiments described herein comprise high-voltage transistors with semiconductor protrusions for field shaping. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As noted above, high voltage transistors, such as gallium nitride (GaN) transistors, generally fall short of realizing the maximum breakdown voltage dictated by the material properties. This is because drain electric field lines concentrate at the edge of the gate and causes premature breakdown. One approach to mitigate the electric field line concentration is to use field plates. Field plates extend over the channel between the gate electrode and the drain contact. The goal of the field plate is to control the distribution of the electric field throughout the device, generally, by spreading the electric field as evenly as possible across regions which can sustain the field. By spreading the required amount of electric field for a given voltage across a larger area of the device, hotspots of electric field lines, which may induce breakdown, are avoided. Field plates and other existing solutions generally try to smoothly decrease the vertical capacitance (of field-plate-to-the-channel) scanning right from the gate electrode to the drain contact. That way, the local pinch-off voltage of the channel slowly increases moving right from the gate electrode to the drain contact, distributing the electric field as evenly as possible.

However, existing field plate architectures are limited in how gradually the field lines can be distributed across the channel between the gate and the drain. That is, the number of knobs available to tune the electric field distribution is limited. One approach is to add additional layers of field plates. However, this increases backend complexity. Another approach is to use a sloped field plate. However, the sloped field plate has manufacturing complexities.

Accordingly, embodiments disclosed herein include high-voltage transistors that include field plates and semiconductor protrusions that extend out from the field plate towards the channel. The use of semiconductor protrusions allows for enhanced control of the tuning of the electric field line distribution. In some embodiments, the semiconductor protrusion is a single body with a non-uniform dopant concentration. For example, a first dopant concentration closer to the gate electrode is larger than a second dopant concentration at an end of the field plate. In other embodiments, a plurality of semiconductor protrusions extend out from the field plate, and a distribution density of the semiconductor protrusions decreases as you move away from the gate electrode. Embodiments also include methods of forming such high-voltage transistors.

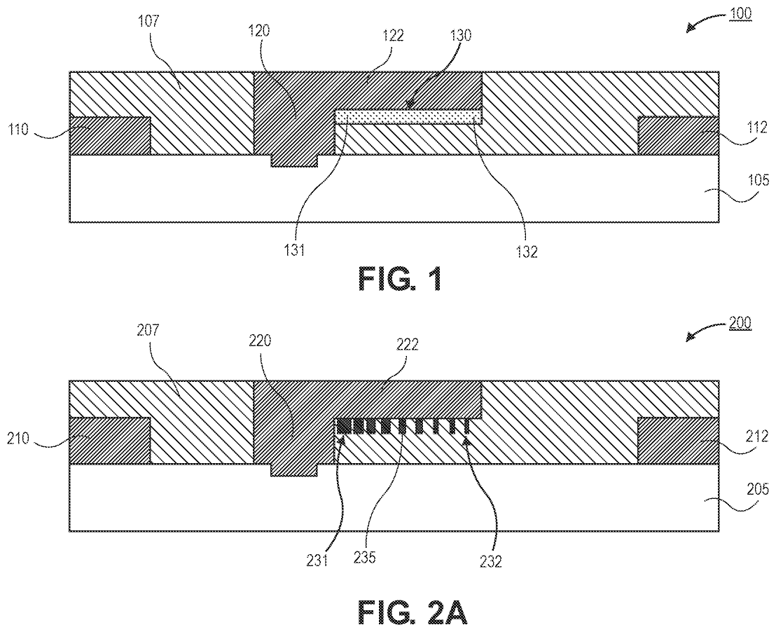

Referring now to FIG. 1, a cross-sectional illustration of a transistor device 100 is shown, in accordance with an embodiment. In an embodiment, the transistor device 100 comprises a semiconductor channel 105. In a particular embodiment, the semiconductor channel 105 comprises gallium and nitrogen (GaN). While shown as a single monolithic layer, it is to be appreciated that the semiconductor channel 105 may comprise a plurality of different layers, as is common in high-voltage transistor architectures. For example, the semiconductor channel 105 may comprise a polarization layer or the like. In embodiments with a GaN semiconductor channel 105, the polarization layer may comprise AlGaN. Additionally, the gate electrode 120 may be separated from the semiconductor channel 105 by a gate dielectric (not shown).

In an embodiment, the transistor device 100 comprises a source contact 110 and a drain contact 112. The source contact 110 and the drain contact 112 may be conductive materials. In other embodiments, the source contact 110 and the drain contact 112 may be highly doped semiconductor regions. In an embodiment, the gate electrode 120 may be provided between the source contact 110 and the drain contact 112. The gate electrode 120 may be a conductive material. In an embodiment, the gate electrode comprises a workfunction metal and a fill metal. In other embodiments, the gate electrode 120 may comprise a single conductor composition.

In an embodiment, the gate electrode 120 may be electrically coupled to a field plate 122. The field plate 122 may be above the semiconductor channel 105. That is, a portion of the dielectric layer 107 may be provided between the field plate 122 and the semiconductor channel 105. In an embodiment, the field plate 122 extends from the gate electrode 120 towards the drain contact 112. While shown as being electrically coupled to the gate electrode 120, other embodiments may include a field plate 122 that is not connected to the gate electrode 120. That is the field plate 122 may be electrically floating in some embodiments.

In an embodiment, a protrusion 130 extends down from the field plate 122 towards semiconductor channel 105. In an embodiment, the protrusion 130 is a semiconductor material. For example, the protrusion 130 may comprise silicon or the like. In the case of a GaN channel, the semiconductor material may be a P-type semiconductor material. In an embodiment, the electric field lines are distributed more evenly by providing a protrusion 130 that has a dopant gradient. For example, a first end 131 of the protrusion 130 that is proximate to the gate electrode 120 may have a higher dopant concentration than a dopant concentration at a second end 132 of the protrusion 130 that is away from the gate electrode 120.

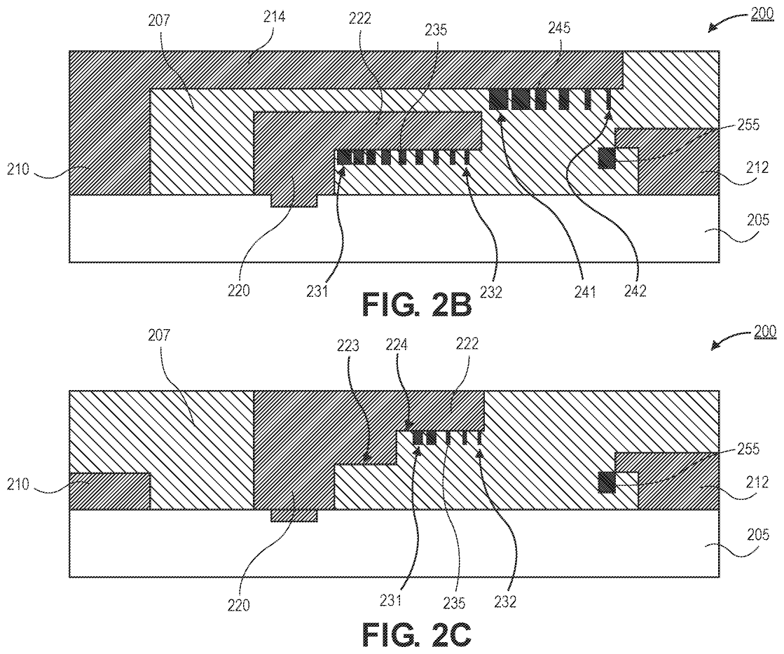

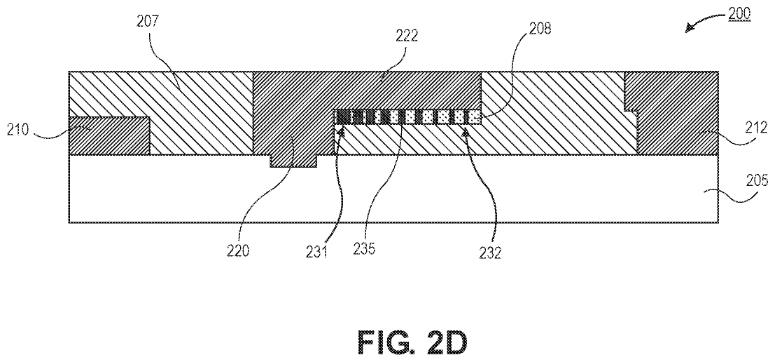

Referring now to FIG. 2A, a cross-sectional illustration of a transistor device 200 is shown, in accordance with an embodiment. The transistor device 200 in FIG. 2A may be substantially similar to the transistor device 100 in FIG. 1, with the exception of the protrusion architecture. For example, the transistor device 200 comprises a channel 205, a source contact 210, a drain contact 212, a gate electrode 220, and a field plate 222. A dielectric 207 may surround the gate electrode 220, the contacts 210, 212, and the field plate 222.

The difference between the transistor device 100 in FIG. 1 and the transistor device 200 in FIG. 2A is that instead of a single protrusion, a plurality of semiconductor protrusions 235 extend down from the field plate 222. In an embodiment, the protrusions 235 may have a non-uniform distribution density. As used herein, a non-uniform distribution density may refer to there being more area of the semiconductor material per unit length. For example, a first end 231 of the protrusions 235 has thicker protrusions 235 and the protrusions are closer together than the protrusions 235 at a second end 232 of the protrusions 235. That is, the distribution density at the first end 231 is greater than the distribution density at the second end 232. By varying the distribution density, a field line distribution improvement is provided even when the individual protrusions comprise the same dopant concentration.

Referring now to FIG. 2B, a cross-sectional illustration of a transistor device 200 is shown, in accordance with an additional embodiment. In an embodiment, the transistor device 200 in FIG. 2B is substantially similar to the transistor device 200 in FIG. 2A, with the addition of a second field plate 214. In an embodiment, the second field plate 214 may extend out from the source contact 210 towards the drain contact 212. In the illustrated embodiment, the second field plate 214 is coupled to the source contact 210. In other embodiments, the second field plate 214 may be electrically floating. In an embodiment, semiconductor protrusions 245 may extend out from the second field plate 214. In an embodiment, the protrusions 245 may be at the end of the second field plate 214 closer to the drain contact 212. The protrusions 245 may have a non-uniform distribution density. For example, a first end 241 of the protrusions has a distribution density that is greater than a distribution density of a second end 242 of protrusions. In an embodiment, a protrusion 255 may also be formed close to a field plate extending away from the drain contact 212.

Referring now to FIG. 2C, a cross-sectional illustration of a transistor device 200 is shown, in accordance with an embodiment. In an embodiment, the transistor device 200 comprises a stepped field plate architecture. That is, a first step 223 is adjacent to the gate electrode 220, and a second step 224 is adjacent to the first step 223. A distance between the second step 224 and the channel 205 may be greater than a distance between the first step 223 and the channel 205. In the illustrated embodiment, protrusions 235 with a non-uniform distribution density extend out from the second step 224. In other embodiments, the protrusions may also extend out from the first step 223. In yet another embodiment, additional steps (with or without protrusions 235) may be included in the transistor device 200.

Referring now to FIG. 2D, a cross-sectional illustration of a transistor device 200 is shown, in accordance with yet another additional embodiment. In an embodiment, the transistor device 200 in FIG. 2D may be substantially similar to the transistor device 200 in FIG. 2A, with the exception of the dielectric layer 208 surrounding the protrusions 235. As shown, a dielectric layer 208 is provided along the length of the field plate 222. In an embodiment, a material composition of the dielectric layer 208 at a first end 231 may be different than a material composition of the dielectric layer 208 at a second end 232. For example, the composition may vary in order to provide a first dielectric constant at the first end 231 and a second dielectric constant at the second end 232. In other embodiments, the dielectric layer 208 may have a uniform composition between the first end 231 and the second end 232. That is, the dielectric layer 208 may include a single material composition. In such an embodiment, the dielectric layer 208 may have a material composition that is different than the material composition of the dielectric layer 207.

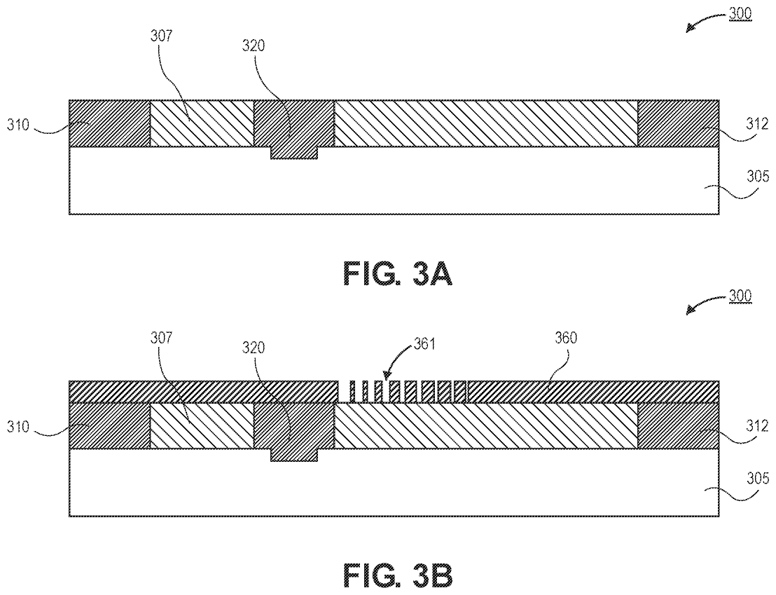

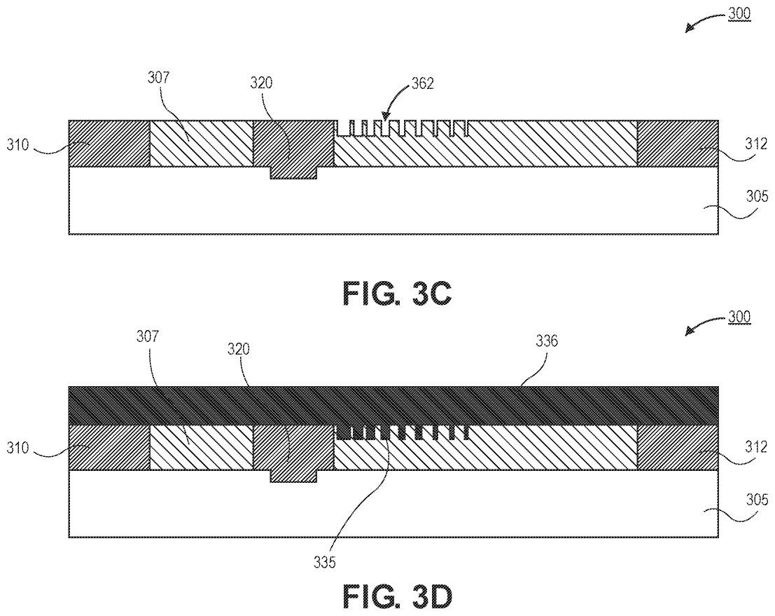

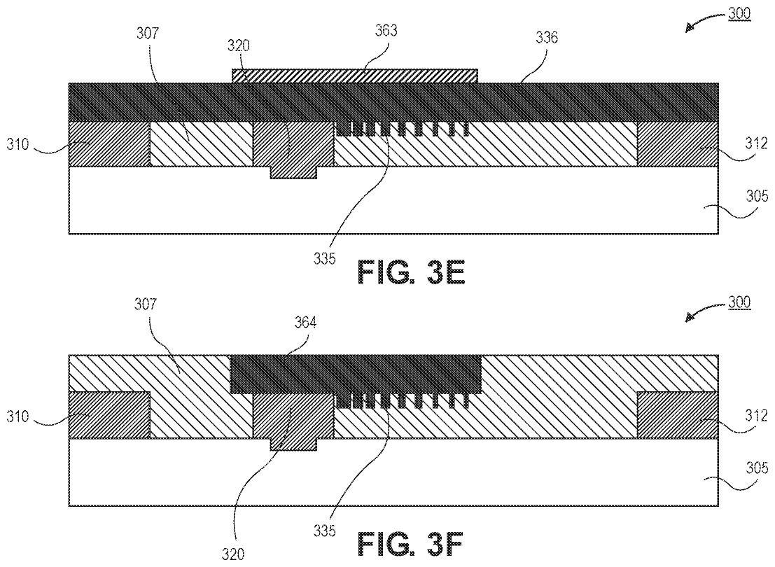

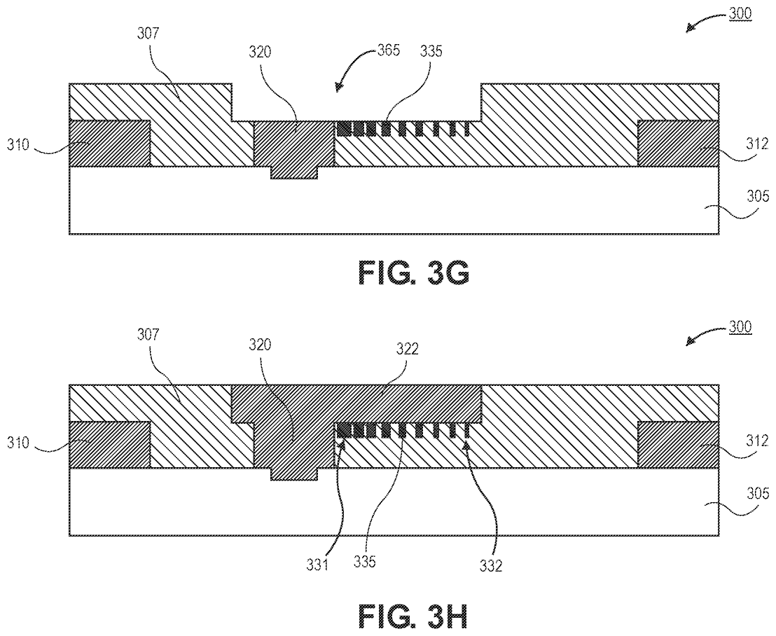

Referring now to FIGS. 3A-3H, a series of cross-sectional illustrations depicting a process for forming a transistor device 300 is shown, in accordance with an embodiment. In the illustrated embodiment, the transistor device 300 may be substantially similar to the transistor device 200 in FIG. 2A. However, it is to be appreciated that similar processing operations may be used to form protrusions in various locations in order to fabricate any of the transistor devices described herein.

Referring now to FIG. 3A, a cross-sectional illustration of a transistor device 300 is shown, in accordance with an embodiment. In an embodiment, the transistor device 300 comprises a channel 305. A source 310, a drain 312, and a gate electrode 320 are provided over the channel 305. In an embodiment, a dielectric layer 307 surrounds the source 310, the drain 312, and the gate electrode 320. In an embodiment, the gate electrode 320 is closer to the source contact 310 than the drain contact 312.

Referring now to FIG. 3B, a cross-sectional illustration of the transistor device 300 after a resist layer 360 is disposed over the dielectric layer 307 and patterned is shown, in accordance with an embodiment. In an embodiment, the resist layer 360 may be patterned with a lithography process. That is, actinic radiation may be used to expose regions of the resist layer 360. The exposed resist layer 360 is then developed in order to form a plurality of openings 361. The openings 361 may have the pattern desired for the semiconductor protrusions.

Referring now to FIG. 3C, a cross-sectional illustration of the transistor device 300 after the pattern of the resist layer 360 is transferred into the dielectric layer 307 and the resist layer 360 is removed is shown, in accordance with an embodiment. In an embodiment, the pattern may be transferred into the dielectric layer 307 with an etching process or the like. The resulting structure of the dielectric layer 307 comprises a plurality of trenches 362. The trenches go into, but not through the dielectric layer 307.

Referring now to FIG. 3D, a cross-sectional illustration of the transistor device 300 after a semiconductor layer 336 is deposited over the dielectric layer 307 is shown, in accordance with an embodiment. In an embodiment, the semiconductor layer 336 fills the trenches 362 in order to form protrusions 335. In an embodiment, the semiconductor layer 336 also extends over the gate electrode 320, the source contact 310, and the drain contact 312.

Referring now to FIG. 3E, a cross-sectional illustration of the transistor device 300 after a second resist layer 363 is provided over the semiconductor layer 336 is shown, in accordance with an embodiment. In an embodiment, the second resist layer 363 may be patterned so that the protrusions 335 and the gate electrode 320 are covered. Remaining portions of the semiconductor layer 336 may be exposed.

Referring now to FIG. 3F, a cross-sectional illustration of the transistor device 300 after the semiconductor layer 336 is etched is shown, in accordance with an embodiment. After the semiconductor layer 336 is etched additional dielectric material 307 may be deposited so that a top surface of the dielectric material 307 is substantially coplanar with a top surface of the remaining portion 364 of the semiconductor layer 336.

Referring now to FIG. 3G, a cross-sectional illustration of the transistor device 300 after the remaining portion 364 is removed is shown, in accordance with an embodiment. In an embodiment, the portion 364 may be removed with an etching process. Removing the portion 364 results in the formation of a trench 365 above the gate electrode 320, and the protrusions 335 are exposed.

Referring now to FIG. 3H, a cross-sectional illustration of the transistor device 300 after the field plate 322 is formed is shown, in accordance with an embodiment. In an embodiment, the field plate 322 is coupled to the gate electrode 320. Additionally, the field plate 322 directly contacts the protrusions 335. In an embodiment, the protrusions 335 have a non-uniform distribution density. For example, a first end 331 of the protrusions 335 has a first distribution density that is larger than a second distribution density of a second end 332.

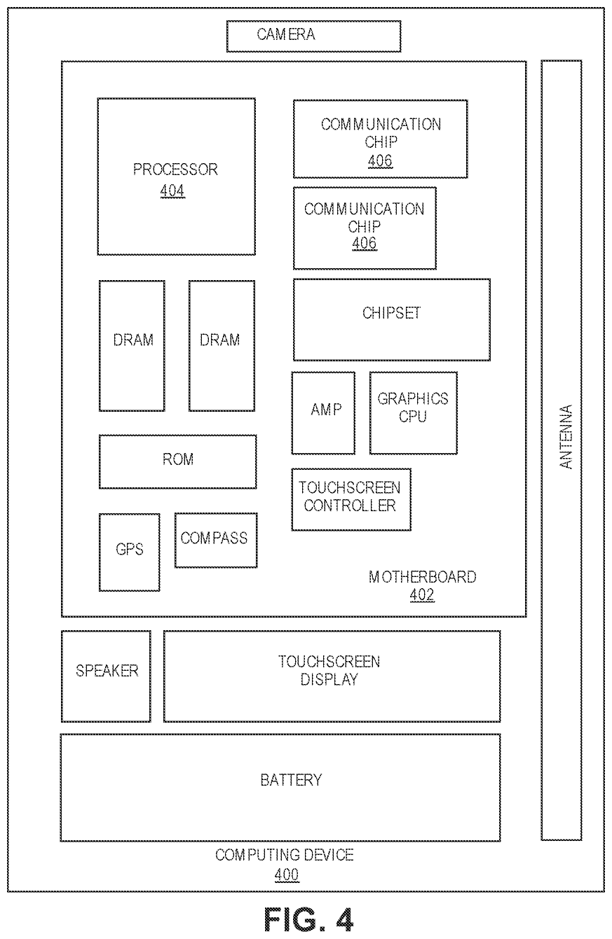

FIG. 4 illustrates a computing device 400 in accordance with one implementation of an embodiment of the disclosure. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In an embodiment, the integrated circuit die of the processor may comprise a transistor device with a field plate that has semiconductor protrusions extending towards the channel from the field plate, as described herein. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In an embodiment, the integrated circuit die of the communication chip may comprise a transistor device with a field plate that has semiconductor protrusions extending towards the channel from the field plate, as described herein.

In further implementations, another component housed within the computing device 400 may comprise a transistor device with a field plate that has semiconductor protrusions extending towards the channel from the field plate, as described herein.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

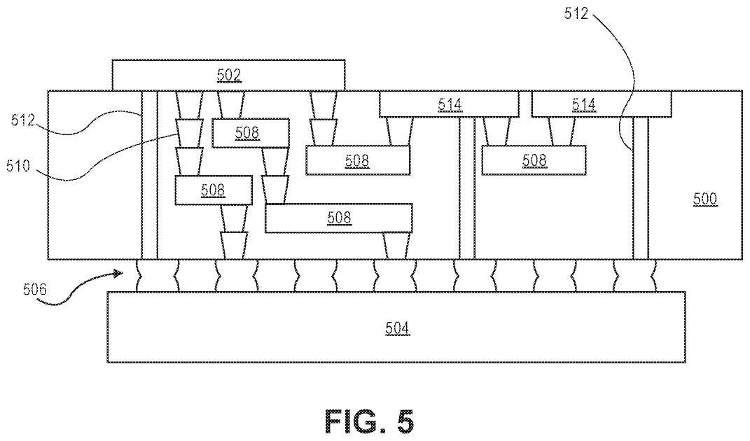

FIG. 5 illustrates an interposer 500 that includes one or more embodiments of the disclosure. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. In an embodiment, one of both of the first substrate 502 and the second substrate 504 may comprise a transistor device with a field plate that has semiconductor protrusions extending towards the channel from the field plate, in accordance with embodiments described herein. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer 500 may be formed of alternate rigid or flexible materials that may include the same materials described above for use in a semiconductor substrate, such as silicon, germanium, and other group III-V and group IV materials.

The interposer 500 may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with embodiments of the disclosure, apparatuses or processes disclosed herein may be used in the fabrication of interposer 500.

Thus, embodiments of the present disclosure may comprise a transistor device with a field plate that has semiconductor protrusions extending towards the channel from the field plate.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a transistor device, comprising: a channel, wherein the channel comprises a first semiconductor material; a source contact at a first end of the channel; a drain contact at a second end of the channel; a gate electrode between the source contact and the drain contact; a field plate that extends from the gate electrode towards the drain contact; and a plurality of protrusions that extend out from the field plate towards the channel, wherein the protrusions comprise a second semiconductor material.

Example 2: the transistor device of Example 1, wherein the protrusions have a first distribution density proximate to the gate electrode and a second distribution density proximate to an end of the field plate, wherein the second distribution density is smaller than the first distribution density.

Example 3: the transistor device of Example 1 or Example 2, wherein the plurality of protrusions are P-doped.

Example 4: the transistor device of Examples 1-3, wherein the channel comprises gallium and nitrogen.

Example 5: the transistor device of Examples 1-4, wherein the plurality of protrusions have a uniform height.

Example 6: the transistor device of Examples 1-5, further comprising: a second field plate extending out from the source, wherein the second field plate extends past an end of the field plate.

Example 7: the transistor device of Example 6, further comprising: a second plurality of protrusions, wherein the second plurality of protrusions extend down from the second field plate, and wherein the second plurality of protrusions comprise a semiconductor material.

Example 8: the transistor device of Example 7, wherein the second plurality of protrusions have a first distribution density towards a center of the second field plate and a second distribution density towards an end of the second field plate, wherein the second distribution density is lower than the first density.

Example 9: the transistor device of Examples 1-8, wherein the field plate has a first stepped surface and a second stepped surface that is further from the channel than the first stepped surface.

Example 10: the transistor device of Example 9, wherein the plurality of protrusions are on the second stepped surface.

Example 11: the transistor device of Examples 1-10, wherein a dielectric surrounding the protrusions has a compositional gradient and/or is compositionally distinct from a second dielectric surrounding the gate electrode and the field plate.

Example 12: a method of forming a transistor, comprising: forming a source contact, a drain contact, and a gate electrode over a channel, wherein the gate electrode is between the source contact and the drain contract, and wherein the channel comprises gallium and nitrogen; disposing a layer around the source contact, the drain contact, and the gate electrode, wherein the layer comprises a dielectric material; patterning an array of trenches into the layer adjacent to the gate electrode; filling the trenches to form a plurality of protrusions, wherein the plurality of protrusions comprise a semiconductor material; and forming a field plate over and in contact with the plurality of protrusions.

Example 13: the method of Example 12, wherein the field plate is electrically coupled to the gate electrode.

Example 14: the method of Example 12 or Example 13, wherein the protrusions have a first distribution density proximate to the gate electrode and a second distribution density proximate to an end of the field plate, wherein the second distribution density is lower than the first distribution density.

Example 15: the method of Examples 12-14, wherein the semiconductor material is a P-type semiconductor material.

Example 16: the method of Examples 12-15, wherein filling the trenches comprises: disposing a semiconductor layer into the trenches and over the layer; masking off a portion of the semiconductor layer to protect the trenches and a top surface of the gate electrode; etching the semiconductor layer so that a semiconductor block and the plurality of protrusions remain; disposing a second layer around the semiconductor block; and removing the semiconductor block to form a field plate trench, wherein the protrusions are left in the trenches.

Example 17: the method of Example 16, wherein the field plate is disposed in the field plate trench.

Example 18: an electronic system, comprising: a board; a package substrate coupled to the board; and a die coupled to the package substrate, wherein the die comprises a transistor device, wherein the transistor device comprises: a channel, wherein the channel comprises a first semiconductor material; a source contact at a first end of the channel; a drain contact at a second end of the channel; a gate electrode between the source contact and the drain contact; a field plate extending from the gate electrode towards the drain contact; and a plurality of protrusions extending out from the field plate towards the channel, wherein the protrusions comprise a second semiconductor material.

Example 19: the electronic system of Example 18, wherein the protrusions have a first distribution density proximate to the gate electrode and a second distribution density proximate to an end of the field plate, wherein the second distribution density is smaller than the first distribution density.

Example 20: the electronic system of Example 18 or Example 19, wherein the plurality of protrusions are P-doped.

What is claimed is:

1. A transistor device, comprising:
a channel, wherein the channel comprises a first semiconductor material;
a source contact at a first end of the channel;
a drain contact at a second end of the channel;
a gate electrode between the source contact and the drain contact;
a field plate that extends from the gate electrode towards the drain contact; and
a plurality of protrusions that extend out from the field plate towards the channel, wherein the protrusions comprise a second semiconductor material.

2. The transistor device of claim 1, wherein the protrusions have a first distribution density proximate to the gate electrode and a second distribution density proximate to an end of the field plate, wherein the second distribution density is smaller than the first distribution density.

3. The transistor device of claim 1, wherein the plurality of protrusions are P-doped.

4. The transistor device of claim 1, wherein the channel comprises gallium and nitrogen.

5. The transistor device of claim 1, wherein the plurality of protrusions have a uniform height.

6. The transistor device of claim 1, further comprising:
a second field plate extending out from the source, wherein the second field plate extends past an end of the field plate.

7. The transistor device of claim 6, further comprising:
a second plurality of protrusions, wherein the second plurality of protrusions extend down from the second field plate, and wherein the second plurality of protrusions comprise a semiconductor material.

8. The transistor device of claim 7, wherein the second plurality of protrusions have a first distribution density towards a center of the second field plate and a second distribution density towards an end of the second field plate, wherein the second distribution density is lower than the first density.

9. The transistor device of claim 1, wherein the field plate has a first stepped surface and a second stepped surface that is further from the channel than the first stepped surface.

10. The transistor device of claim 9, wherein the plurality of protrusions are on the second stepped surface.

11. The transistor device of claim 1, wherein a dielectric surrounding the protrusions has a compositional gradient and/or is compositionally distinct from a second dielectric surrounding the gate electrode and the field plate.

12. A method of forming a transistor, comprising:
forming a source contact, a drain contact, and a gate electrode over a channel, wherein the gate electrode is between the source contact and the drain contract, and wherein the channel comprises gallium and nitrogen;
disposing a layer around the source contact, the drain contact, and the gate electrode, wherein the layer comprises a dielectric material;
patterning an array of trenches into the layer adjacent to the gate electrode;
filling the trenches to form a plurality of protrusions, wherein the plurality of protrusions comprise a semiconductor material; and
forming a field plate over and in contact with the plurality of protrusions.

13. The method of claim 12, wherein the field plate is electrically coupled to the gate electrode.

14. The method of claim 12, wherein the protrusions have a first distribution density proximate to the gate electrode and a second distribution density proximate to an end of the field plate, wherein the second distribution density is lower than the first distribution density.

15. The method of claim 12, wherein the semiconductor material is a P-type semiconductor material.

16. The method of claim 12, wherein filling the trenches comprises:
disposing a semiconductor layer into the trenches and over the layer;
masking off a portion of the semiconductor layer to protect the trenches and a top surface of the gate electrode;
etching the semiconductor layer so that a semiconductor block and the plurality of protrusions remain;
disposing a second layer around the semiconductor block; and
removing the semiconductor block to form a field plate trench, wherein the protrusions are left in the trenches.

17. The method of claim 16, wherein the field plate is disposed in the field plate trench.

18. An electronic system, comprising:
a board;
a package substrate coupled to the board; and
a die coupled to the package substrate, wherein the die comprises a transistor device, wherein the transistor device comprises:
a channel, wherein the channel comprises a first semiconductor material;
a source contact at a first end of the channel;
a drain contact at a second end of the channel;
a gate electrode between the source contact and the drain contact;
a field plate extending from the gate electrode towards the drain contact; and
a plurality of protrusions extending out from the field plate towards the channel, wherein the protrusions comprise a second semiconductor material.

19. The electronic system of claim 18, wherein the protrusions have a first distribution density proximate to the gate electrode and a second distribution density proximate to an end of the field plate, wherein the second distribution density is smaller than the first distribution density.

20. The electronic system of claim 18, wherein the plurality of protrusions are P-doped.
